(19) United States
(12) Patent Application Publication
(10) Pub. No.: US 2020/0264236 A1
(43) Pub. Date: Aug. 20, 2020

(54) BUILDING MANAGEMENT SYSTEM WITH REMAINING BATTERY ENERGY ESTIMATION FOR WIRELESS DEVICES

(71) Applicant: Johnson Controls Technology Company, Auburn Hills, MI (US)

(72) Inventor: Timothy C. Gamroth, Dousman, WI (US)

(73) Assignee: Johnson Controls Technology Company, Auburn Hills, MI (US)

(21) Appl. No.: 16/277,493

(22) Filed: Feb. 15, 2019

(51) Int. Cl. G01R 31/371; G01R 31/367; G01R 31/36; H02J 50/80; H02J 13/00

(52) U.S. Cl. CPC G01R 31/371; G01R 31/367; H02J 13/0003; G01R 31/3647; H02J 50/80; G01R 31/3648

(57) ABSTRACT

A wireless device includes a battery that stores and discharges energy to power the wireless device, an event detector that detects one of more energy consumption events occurring in the wireless device, an event counter that accumulates a total number of each of the energy consumption events detected by the event detector, an energy database that stores energy data indicating the pre-determined amount of energy consumption associated with each of the energy consumption events, and a wireless radio configured to transmit a message containing the amount of energy remaining in the battery.

### BACKGROUND

The present disclosure relates generally to methods for managing building systems. The present disclosure relates more particularly to systems and methods estimating the remaining energy in a battery.

A building management system (BMS) is, in general, a system of devices configured to control, monitor, and manage equipment in or around a building or building area. A BMS can include, for example, a HVAC system, a security system, a lighting system, a fire alerting system, any other system that is capable of managing building functions or devices, or any combination thereof. Wireless devices such as wireless sensors may use a large portion of battery energy to monitor the energy levels of the battery.

Conventional methods of monitoring battery energy include circuitry configured to monitory battery current or voltage. Those methods decrease the life of the battery quicker than expected, causing the battery to run out of energy before a planned maintenance interval. Also, conventional methods of installing battery-monitoring circuit may increase costs of batteries. It would be desirable to provide a method for monitoring battery energy which overcomes the disadvantages of established methods.

### SUMMARY

One implementation of the present disclosure is a wireless device including a battery that stores and discharges energy to power the wireless device, an event detector that detects one of more energy consumption events occurring in the wireless device, an event counter that accumulates a total number of each of the energy consumption events detected by the event detector, an energy database that stores energy data indicating the pre-determined amount of energy consumption associated with each of the energy consumption events, and a wireless radio configured to transmit a message containing the amount of energy remaining in the battery.

In some embodiments, the wireless device includes a sensors and the message includes one or more measurements of an environmental variable recorded by the sensor.

In some embodiments, the event detector identifies each energy consumption event and classifies the energy consumption event as one or more different energy consumption events.

In some embodiments, the event counter increments a counter associated with the energy consumption events each time that an energy consumption event is detected. In other embodiments, the event counter sums the counts associated with the energy consumption events each time that an energy consumption event is detected.

In some embodiments, the energy data stored in the energy database further includes a battery energy capacity value.

Another implementation of the present disclosure is a method for operating a wireless device in a building control system including storing energy in a battery of the wireless device and discharging the energy from the battery to power the wireless device, detecting one or more energy consumption events occurring in the wireless device, each of the energy consumption events corresponding to a function performed by the wireless device and having a pre-determined amount of energy consumption associated therewith, accumulating a total number of each of the energy consumption events, obtaining, from an energy database, the pre-determined amount of energy consumption associated with each of the energy consumption events, determining an amount of energy remaining in the battery using the total number of each of the energy consumption events and the pre-determined amount of energy consumption associated with each of the energy consumption events.

In some embodiments, the one or more energy consumption events includes the measurement of an environmental variable recorded by the sensor.

In some embodiments, the event detector detects and identifies one or more energy consumption events of the wireless device.

In some embodiments, the event counter counts and sums one or more energy consumption events of the wireless device.

In some embodiments, the energy database stores the pre-determined energy values referenced to the energy consumption events of the wireless device and a battery energy capacity value.

In some embodiments, the energy calculator obtains the pre-determined energy value, subtracts the pre-determined energy value associated with the one or more energy consumption events from a battery energy capacity value, and determines a remaining battery energy value.

Yet another implementation of the present disclosure is a building control system including a wireless device and a controller. The wireless device includes a battery that stores and discharges energy to power the wireless device, an event detector that detects one of more energy consumption events occurring in the wireless device, an event counter that accumulates a total number of each of the energy consumption events detected by the event detector, a wireless radio that transmits a message including the total number of each of the energy consumption events. The controller includes a message parser that parses the message to extract the total number of each of the energy consumption events, an energy database storying energy data indicating the pre-determined amount of energy consumption associated with the energy consumption events, and an energy calculator that calculates an amount of energy remaining in the battery using the total number of each of the energy consumption events and the pre-determined amount of energy consumption associated with each of the energy consumption events.

In some embodiments, the wireless device includes a sensor and the message includes measurements of an environmental variable recorded by the sensor.

In some embodiments, the event detector identifies an energy consumption event and classifies the energy consumption event as one or more different energy consumption events, each of the different energy consumption events corresponding to a different function performed by the wireless device.

In some embodiments, the event counter increments a counter associated with the energy consumption events each time that an energy consumption event is detected.

In some embodiments, the event counter sums the counter associated with the energy consumption events each time that an energy consumption event is detected.

In some embodiments, the energy data stored in the energy database includes an indication of a battery energy capacity value.

Those skilled in the art will appreciate that the summary is illustrative only and is not intended to be in any way limiting. Other aspects, inventive features, and advantages of the devices and/or processes described herein, as defined solely by the claims, will become apparent in the detailed description set forth herein and taken in conjunction with the accompanying drawings.

### BRIEF DESCRIPTION OF THE DRAWINGS

FIG. 1 is a drawing of a building equipped with a HVAC system in which the systems and method of the present disclosure may be implemented, according to some embodiments.

FIG. 2 is a block diagram of a wireless device and controller in which the systems and method of the present disclosure may be implemented, according to some embodiments.

FIG. 3 is a block diagram of a wireless device and controller in which the systems and method of the present disclosure may be implemented, according to some embodiments.

FIG. 4 is a general flowchart of the process to calculate remaining battery energy, according to some embodiments.

FIG. 5 is a detailed flowchart of the process to calculate remaining battery energy by the system of FIG. 2, according to some embodiments.

FIG. 6 is a detailed flowchart of the process to calculate remaining battery energy by the system of FIG. 3, according to some embodiments.

FIG. 7 is a block diagram illustrating the process of FIG. 5, according to some embodiments.

FIG. 8 is a block diagram illustrating the process of FIG. 6, according to some embodiments.

FIG. 9 is a plot illustrating the energy consumption of the systems in FIGS. 2 and 3, according to some embodiments.

FIG. 10 is a plot illustrating the estimation of battery life of the plot in FIG. 9, according to some embodiments.

### DETAILED DESCRIPTION

### Overview

Referring generally to the FIGURES, a building management system, feedback controller, and components thereof are shown according to various exemplary embodiments. At the most fundamental level, feedback control leverages measurements to make decisions about how to manipulate the inputs of a system so that the controlled system achieves an expected or desirable behavior. Traditionally, wired sensors are used in feedback control systems. However, with the increasing availability and capacity of wireless sensors and wireless communication networks, wireless sensors are becoming a viable alternative to wired sensors.

In a building HVAC system, wireless sensors may be used to monitor a variety of building conditions such as temperature, humidity, pressure, airflow, etc. For example, a wireless temperature sensor may be used to measure the temperature of a building zone and send zone temperature measurements to a feedback controller. The controller subsequently computes control inputs that ensure the zone temperature (e.g., the measured variable) is maintained at a zone temperature setpoint.

One of the major challenges of using battery-powered wireless sensors within feedback control applications is that the battery power consumption required to monitor battery life may be significant. Further, another challenge of using battery-powered wireless sensors is improper utilization of the battery life in the device. Many batteries may come with a life expectancy to assist users with planning a maintenance schedule, but these life expectancies may not consider the application of the device that the battery is powering. As a result, the full capacity of the battery's energy may not be consumed, or the battery's energy capacity is consumed entirely before maintenance is performed to change out the battery. The present disclosure offers systems and methods to estimate the remaining battery capacity in a wireless device to reduce the need to utilize significant battery energy to monitor the battery's life and to accurately output when the battery requires maintenance.

One technique for estimating the battery life of a wireless sensor is to monitor the state (e.g., sleep, wake, measure, etc.) of a wireless measurement device. Since wireless measurement devices are relatively simple electromechanical devices, their number of states is limited. When a wireless measurement device changes state, this may be considered an energy-consumption event. Each energy-consumption event requires a known energy amount to execute. For example, for a wireless measurement device to measure a value of a variable, the energy required to measure the value is known. In addition, the energy capacity of the battery is another known value. By identifying an event occurring and accumulating the number of occurrences, the resulting battery life after the event(s) can be calculated. This state-based method allows for a simplified process for estimating the battery life of a wireless measurement device.

Before discussing the FIGURES in detail, it should be noted that the examples provided in the present disclosure are illustrative only and should not be regarded as limiting.

### Building Management System and HVAC System

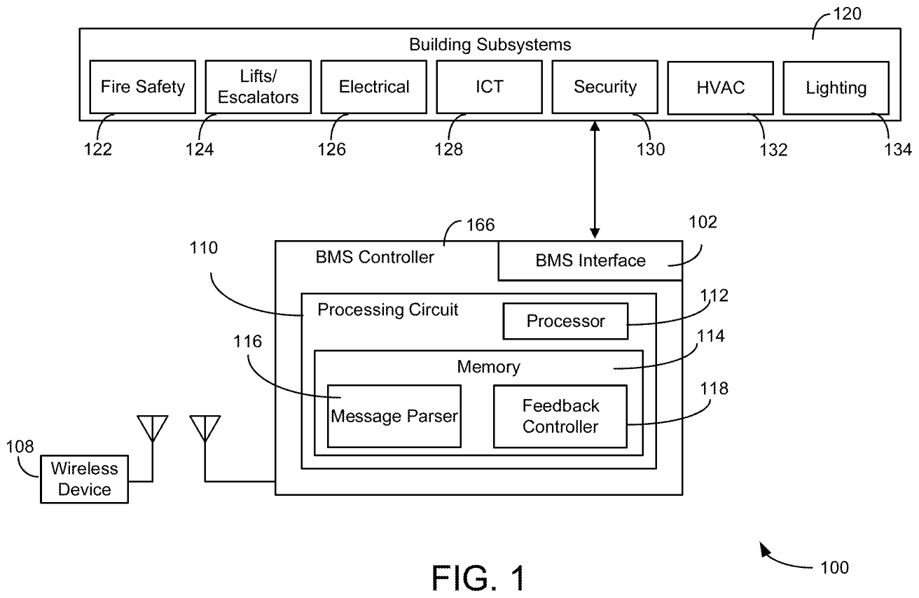

Referring to FIG. 1, a block diagram of a building management system (BMS) 100 is shown, according to an exemplary embodiment. BMS 100 may be implemented in a building to automatically monitor and control various building functions. BMS 100 is shown to include BMS controller 166 and a plurality of building subsystems 120. Building subsystems 120 are shown to include a fire safety system 122, a lift/escalators subsystem 124, a building electrical subsystem 126, an information communication technology (ICT) subsystem 128, a security subsystem 130, a HVAC subsystem 132, and a lighting subsystem 134. In various embodiments, building subsystems 120 can include fewer, additional, or alternative subsystems. For example, building subsystems 120 may also or alternatively include a refrigeration subsystem, an advertising or signage subsystem, a cooking subsystem, a vending subsystem, a printer or copy service subsystem, or any other type of building subsystem that uses controllable equipment and/or sensors to monitor or control a building.

Each of building subsystems 120 may include any number of devices, controllers, and connections for completing its individual functions and control activities. For example, HVAC subsystem 132 may include a chiller, a boiler, any number of air handling units, economizers, field controllers, supervisory controllers, actuators, temperature sensors, and other devices for controlling the temperature, humidity, airflow, or other variable conditions within a building. Lighting subsystem 134 may include any number of light fixtures, ballasts, lighting sensors, dimmers, or other devices configured to controllably adjust the amount of light provided to a building space. Security subsystem 130 may include occupancy sensors, video surveillance cameras, digital video recorders, video processing servers, intrusion detection devices, access control devices and servers, or other security-related devices.

BMS controller 166 may communicate with a wireless device 108. In some embodiments, device 108 includes a wireless sensor. For example, device 108 may include wireless communications abilities and may be able to transmit measured and/or battery data values to BMS controller 166. Device 108 may be a wireless standalone sensor that is not part of another device. For example, device 108 may be a wireless sensor hidden in a wall, attached to a light fixture, etc. and may be battery operated. In some embodiments, device 108 is integrated with a subsystem of building subsystems 120. For example, device 108 may be a sensor installed in a duct of HVAC subsystem 132. Device 108 may contain one or more of a variety of sensors (e.g., temperature sensors, pressure sensors, etc.) used to monitor a building.

In some embodiments, device 108 may be a smartphone or tablet. In other embodiments, device 108 may be a laptop or desktop computer, and may not be wireless. Wireless device 108 may be any device which is capable of communication with BMS controller 166 and is not limited to the explicitly enumerated devices. It is contemplated that wireless device 108 may communicate with building subsystems 120 directly. BMS controller 166 may transmit building data to device 108 for processing or analysis. Building data may include any relevant data obtained from a component within the building or pertaining to a portion or subsystem of the building. For example, building data may be data from sensors, status control signals, feedback signals from a device, calculated metrics, setpoints, configuration parameters, etc. In some implementations, building data is derived from data collected.

Wireless device 108 may transmit control data to BMS controller 166 in some embodiments. Control data may be any data which affects operation of the BMS. In some embodiments, control data may control building subsystems 120 through BMS controller 166. For example, wireless device 108 may send a signal with a command to enable intrusion detection devices of security subsystem 130. Wireless device 108 may receive building data from BMS controller 166 through communications interface 104.

In some embodiments, device 108 may transmit battery data to BMS controller 166. Battery data may be any data relating to battery energy or usage in device 108. In some embodiments, wireless device 108 may transmit battery data consisting of an amount of energy remaining in the battery and an estimated time remaining until the energy in the battery is completely consumed. In other embodiments, device 108 may transmit event data to BMS controller 166. Event data may be any data relating to events (e.g., sleep, wake, measure, etc.) that have occurred in device 108. For example, wireless device 108 may transmit data consisting of an identification of an event and a count of the occurrences of the event.

BMS controller 166 also includes BMS interface 102. BMS interface 102 may facilitate communications between BMS controller 166 and building susbsystems (e.g., HVAC, lighting, security, lifts, power distribution, etc.). BMS interface 102 can be or include wired or wireless communications interfaces (e.g., jacks, antennas, transmitters, receivers, transceivers, wire terminals, etc.) for conducting data communications with building subsystems 120 or other external systems or devices. In various embodiments, communication via BMS interface 102 may be direct (e.g., local wired or wireless communications) or via a communications network (e.g., a Wan, the Internet, a cellular network, etc.). For example, BMS interface 102 can include an Ethernet card and port for sending and receiving data via an Ethernet-based communications link or network. In another example, BMS interface 102 can include a WiFi transceiver for communicating via a wireless communications network. In yet another example, BMS interface 102 may include cellular or mobile phone communications transceivers.

Still referring to FIG. 1, BMS controller 166 is shown to include a processing circuit 110. Processing circuit 110 includes a processor 112 and memory 114. Processor 112 can be implemented as a general-purpose processor, an application specific integrated circuit (ASIC), one or more field programmable gate arrays (FPGAs), a group of processing components, or other suitable electronic processing components.

Memory 114 (e.g., memory, memory unit, storage device, etc.) may include one or more devices (e.g., RAM, ROM, Flash memory, hard disk storage, etc.) for storing data and/or computer code for completing or facilitating the various processes, layers and modules described in the present application. Memory 114 may be or include volatile memory or non-volatile memory. Memory 114 may include database components, object code components, script components, or any other type of information structure for supporting the various activities and information structures described in the present application. According to an exemplary embodiment, memory 114 is communicably connected to processor 112 via processing circuit 110 and includes computer code for executing (e.g., by processing circuit 110 and/or processor 112) one or more processes described herein.

In some embodiments, BMS controller 166 is implemented within a single computer (e.g., one server, one housing, etc.). In various other embodiments BMS controller 166 may be distributed across multiple servers or computers (e.g., that can exist in distributed locations). For example, BMS controller 166 may be implemented as part of a METASYS® brand building automation system, as sold by Johnson Controls Inc. In other embodiments, BMS controller 166 may be a component of a remote computing system or cloud-based computing system configured to receive and process data from one or more building management systems. For example, BMS controller 166 may be implemented as part of a PANOPTIX® brand building efficiency platform, as sold by Johnson Controls Inc. In other embodiments, BMS controller 166 may be a component of a subsystem level controller (e.g., a HVAC controller), a subplant controller, a device controller (e.g., a chiller controller, etc.), a field controller, a computer workstation, a client device, or any other system or device that receives and processes data.

Still referring to FIG. 1, memory 114 is shown to include a message parser 116 and a feedback controller 118. Message parser 116 and feedback controller 118 may be configured to receive inputs from building subsystems 120, wireless device 108, and other data sources, determine optimal control actions for building subsystems 120 based on the inputs, generate control signals based on the optimal control actions, and provide the generated control signals to building subsystems 120. The following paragraphs describe some of the general functions performed by each of message parser 116 and feedback controller 118 in BMS 100.

Message parser 116 may be configured to parse data received by BMS controller 166. For example, a message containing multiple data values (e.g., measured values and/or battery energy value) may be received by BMS controller 166. Message parser 116 may be configured to parse the message and extract the multiple data values. Message parser 116 may provide one value at a time to feedback controller 118. In yet other embodiments, message parser 116 may provide only values of a certain type to feedback controller 118. For example, message parser 116 may only provide measured values to feedback controller 118. In some embodiments, message parser 116 can work with feedback controller 118 to optimize building performance (e.g., efficiency, energy use, comfort, or safety) based on inputs received at BMS interface 102.

Message parser 116 may be configured to parse battery data received by BMS controller 166. In some embodiments, a message containing a remaining battery energy value may be received by BMS controller 166. Message parser 116 may be configured to parse the message and extract the battery energy value. In other embodiments, a message containing an event identification (e.g., sleep, wake, measure, etc.) and an event count may be received by BMS controller 166. Message parser 116 may be configured to parse the message and extract the event identification and event count.

### Transmission System Architecture

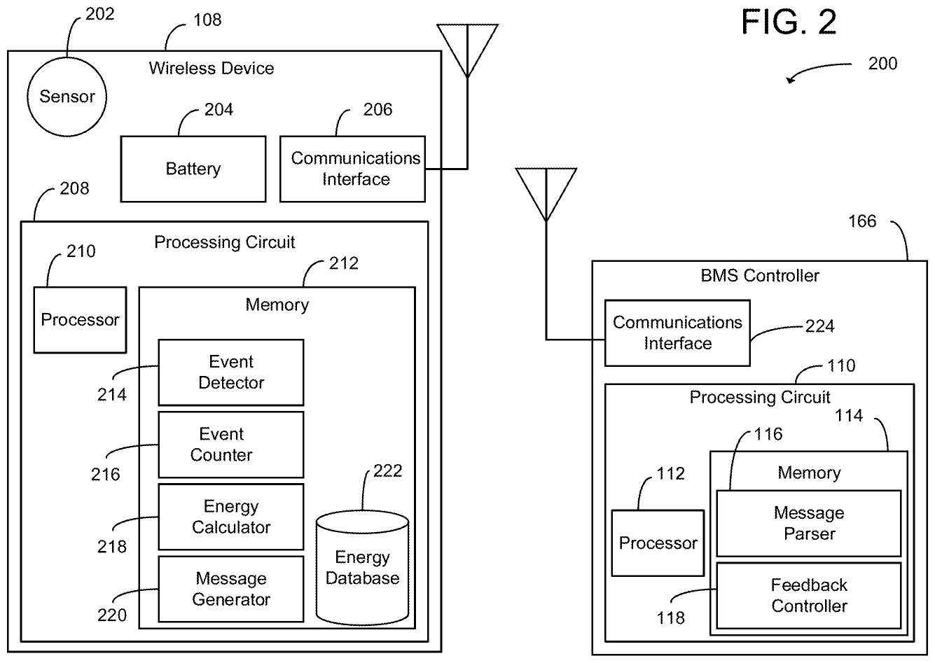

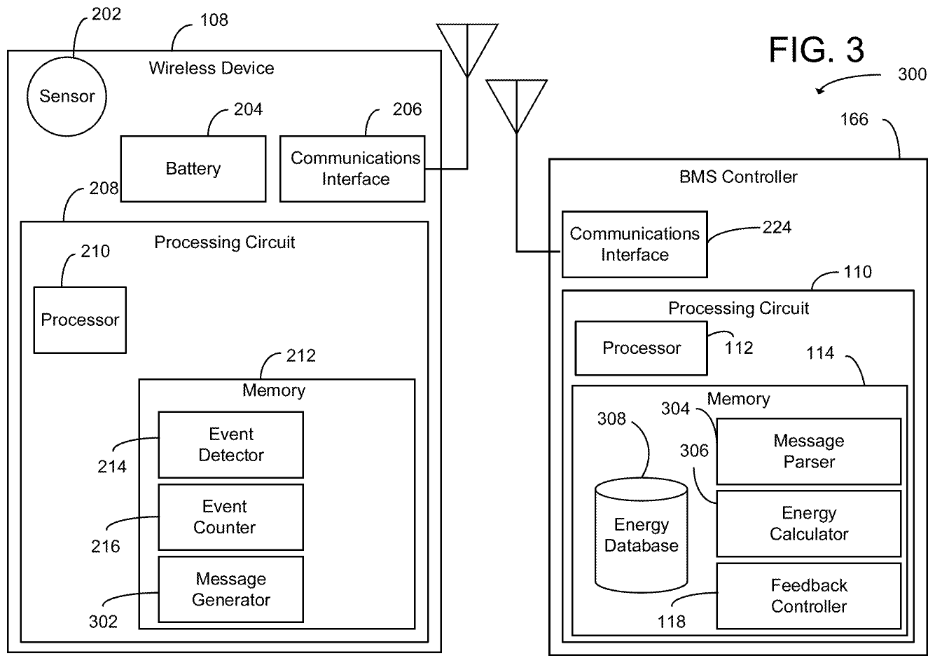

Referring now to FIGS. 2-3, systems 200 and 300 for wirelessly transmitting data are shown, according to two exemplary embodiments. The transmitted data may include measured values, remaining battery energy values, event identification, event count or any combination thereof. Systems 200 and 300 are shown to include wireless device 108 and BMS controller 166. Wireless device 108 is shown to include a sensor 202, a battery 204, a communications interface 206, and a processing circuit 208.

Sensor 202 may measure a variable of interest and provide measured data values to processing circuit 208. Sensor 202 may be a temperature sensor, humidity sensor, enthalpy sensor, pressure sensor, lighting sensor, flow rate sensor, voltage sensor, valve position sensor, load sensor, resource consumption sensor, and/or any other type of sensor capable of measuring a variable of interest in BMS 100. In some embodiments, sensor 202 includes a plurality of sensors, and wireless device 108 may generate multiple messages or generate one message, each containing measurements for multiple measured variables. In some embodiments, sensor 202 is a single sensor and wireless device 108 may generate a single message containing multiple measurements containing data for the singular measured variable.

Sensor 202 may collect data values continuously, at regular intervals, or intermittently at non-regular intervals. For example, sensor 202 may collect temperature data in a particular zone of a building every minute. In some embodiments, sensor 202 may collect multiple values for multiple variables at the same time, or at different frequencies. For example, sensor 202 may be a combination sensor, and may collect air temperature data every minute and local humidity every five minutes. The length of time between data collections by sensor 202 is referred to herein as the measurement period and/or the measurement interval.

Sensor 202 may be any battery-operated sensor, such that sensor 202 does not need an external power source. In some embodiments, sensor 202 receives power from battery 204 within wireless device 108. Battery 204 may generate electrical power via a chemical reaction (e.g., lithium-ion, alkaline, lead-acid, etc.) and transmit the electrical power to the various modules in wireless device 108. Battery 204 may have a rated energy capacity. For example, battery 204 may be a manganese/alkaline battery rated at 2.4 amp-hours. In some embodiments, the energy capacity may be consumed by various events occurring in the wireless device (e.g., wake, measure, generate message, etc.).

Processing circuit 208 is shown to include processor 210 and memory 212. Processor 210 may be any controller component capable of processing data. For example, processor 210 may be capable of receiving, permuting, and outputting data. In some embodiments, processor 210 may process measured values collected by sensor 202. Memory 212 may be capable of storing data. In some embodiments, memory 212 may store measured values collected by sensor 202.

Referring particularly to FIG. 2, system 200 is shown, according to an exemplary embodiment. In system 200, the remaining battery energy value is calculated in wireless device 108, the value is included in a message generated by message generator 220, and transmitted to BMS controller 166 wirelessly. In system 200, memory 212 is shown to include event detector 214, event counter 216, energy calculator 218, message generator 220, and energy database 222. The functions of these components are described in greater detail below.

Event detector 214 may be a module of memory 212. In some embodiments, event detector 214 may be a memory module which may contain instructions to be executed by processor 210. Event detector 214 may use states of wireless device 108 to detect and identify an energy-consumption event occurring. In some embodiments, event detector 214 may be implemented in hardware, as a circuit. In other embodiments, event detector 214 may be implemented in software, as computer-executable code. Event detector 214 may be implemented as any combination of hardware and software. Any module in the present disclosure may be implemented as solely hardware, solely software, or a combination of hardware and software.

Event counter 216 may be a module of memory 212 configured to accumulate events occurring in wireless device 108. In some embodiments, event counter 216 communicates with event detector 214. For example, if event detector 214 detects an event, then event counter 216 receives notice that an event has occurred. In some embodiments, event counter 216 sums the event counts in wireless device 108. For example, if wireless device 108 begins in sleep mode, wakes up, records a measurement, and returns to sleep, the sum of events includes two sleep events, 1 wake event, and 1 measurement event.

Memory 212 is shown to include energy calculator 218. Energy calculator 218 may be a module of memory 212 configured to calculate the remaining battery life. In some embodiments, energy calculator 218 may communicate with energy database 222 to retrieve the battery energy capacity value of the battery of wireless device 108. In some embodiments, energy calculator 218 may communicate with energy database 222 to retrieve energy values for events occurring in wireless device 108. For example, energy calculator 218 may retrieve the energy value from energy database 222 for wireless device 108 to record a measurement.

In some embodiments, energy calculator 218 may calculate the remaining battery life by subtracting the energy value of the event from the battery energy capacity value. In some embodiments, energy calculator 218 may store the resulting remaining battery life value for future calculations in memory 212. For example, if energy calculator 218 calculated that the remaining battery life is 100 J, then memory 212 may store this value for the next calculation in energy calculator 218.

Energy database 222 may be a memory bank of memory 212 configured to store energy values of events occurring in wireless device 108. In some embodiments, energy database 222 may include a battery energy capacity value of the battery 204. In some embodiments, energy database 222 may communicate event energy values to energy calculator 218. In some embodiments, energy database 222 may store a remaining battery life value to be used by energy calculator 218.

Still referring to FIG. 2, memory 212 is shown to include message generator 220. Message generator 220 may be a module of memory 212 configured to generate a message for transmitting from wireless device 108 to BMS controller 166. In some embodiments, message generator 220 may generate a message which contains one or more measured values and a remaining battery energy value for transmitting from wireless device 108 to BMS controller 166.

Still referring to FIG. 2, wireless device 108 and BMS controller 166 are shown to include communications interfaces 206 and 224. Communications protocols may include Wi-Fi, Bluetooth, NFC, etc. In some embodiments, other communications interfaces and components may be included, such as a wired connection. Communications interfaces 206 and 224 may contain transceivers capable of transmitting and receiving data through an antenna. Communications interfaces 206 and 224 may be different chips and may use different hardware while using the same wireless communications protocol. Communications interfaces 206 and 224 may operate using any frequency interface, such as RF. Communications interfaces 206 and 224 may use frequencies outside of the RF range and may not be radio chips. In some embodiments, communications interfaces 206 and 224 may communicate using other frequency ranges, such as IR. Communications interfaces 206 and 224 may utilize any communications interface and are not limited to those specifically enumerated.

Still referring to FIG. 2, BMS controller 166 is shown to include communications interface 224 and processing circuit 110. Processing circuit 110 is shown to include processor 112 and memory 114. Memory 114 is shown to include message parser 116 and feedback controller 118. These components may be the same or similar as previously described with reference to FIG. 1. For example, message parser 116 may parse messages generated by message generator 220 and received by BMS controller 166. In some embodiments, messages are received directly by message parser 116. Message parser 116 may communicate with feedback controller 118. In some embodiments, message parser 116 parses a message, extracts a plurality of data values from the message, and provides the data values to feedback controller 118 at regular intervals.

Referring now to FIG. 3, system 300 is shown, according to an exemplary embodiment. System 300 is shown to include many of the same components as system 200 of FIG. 2. Reused reference numbers indicate similar components. In system 300, the remaining battery life may be calculated by BMS controller 166 and therefore energy calculator 306 and energy database 308 may be included in BMS controller 166 rather than wireless device 108. Wireless device 108 is shown to include, in the exemplary embodiment of FIG. 3, sensor 202, battery 204, communications interface 206, and processing circuit 208. Processing circuit 208 is shown to include processor 210 and memory 212. Memory 212 is shown to include event detector 214, event counter 216 and message generator 302. Message generator 302 may generate messages containing one or more values of the measured variable, one or more event identifications and one or more event counts. In some embodiments, the messages include a single value of the measured variable. In other embodiments, the messages include multiple values of the measured variable. Communications interface 206 may transmit the messages to BMS controller 166 at the transmission interval.

BMS controller 166 is shown to include communications interface 224 and processing circuit 110. Processing circuit 110 is shown to include processor 112 and memory 114. Memory 114 is shown to include message parser 304, energy calculator 306, energy database 308, and feedback controller 118. In some embodiments, message parser 304 receives messages from wireless device 108 and parses messages into values for inputting to feedback controller 118. In some embodiments, message parser 304 parses messages into identification and counts of events that have occurred in wireless device 108. In some embodiments, energy calculator 306 may communicate with message parser 304 to retrieve the parsed event identification and count. In some embodiments, energy calculator 306 may communicate with energy database 308 to retrieve event energy values. In some embodiments, energy calculator 306 may calculate the remaining battery energy value.

### Estimating Remaining Battery Life

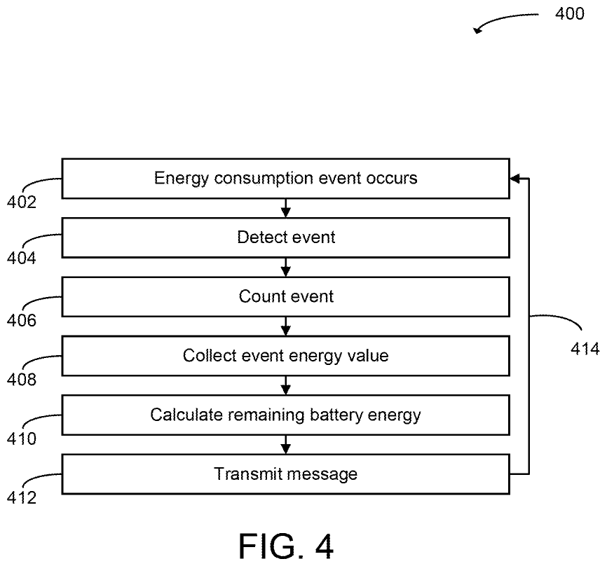

Referring now to FIG. 4, a flowchart illustrating a process 400 for estimating battery life is shown, according to an exemplary embodiment. Process 400 is shown to include an energy consumption event (e.g., recording a measurement, transmitting a message, performing a calculating, storying data in memory, etc.) occurring in step 402. Step 402 may be performed by a wireless device which may contain a sensor. Process 400 is shown to include detecting an energy consumption event in step 404. In some embodiments, the energy-consumption event may be identified. For example, once an event is detected in step 404, step 404 may further involve identifying the event as the device recording a measurement. In some embodiments, different energy consumption events consume different amounts of energy. For example, the energy consumed to transmit a measurement may be larger than the energy consumed to record a measurement).

The event may then be counted in step 406. In some embodiments, step 406 may involve summing the events. In some embodiments, step 406 may include counting how many times each type of energy-consumption event has occurred within a given time period. For example, counting may include 8 occurrences of recording a measurement, 3 occurrences of storing data, and 2 occurrences of transmitting a message. Step 408 may involve collecting the energy value of an occurring event from the energy database. In some embodiments, step 408 may involve retrieving the energy capacity value of the battery from the energy database. Step 410 may involve calculating the remaining energy of the battery. In some embodiments, this may include subtracting the energy value of an event from the battery energy capacity. Step 412 involves transmitting a message. In some embodiments, the message transmitted in step 412 may contain a measured value, remaining battery energy value, event identification, event count, or any combination thereof. Step 414 involves returning to step 402, which includes process 400 starting over. In some embodiments, process 400 may include fewer steps. For example, process 400 may not include step 412 (e.g., transmitting a message) each time step 402 occurs (e.g., an energy consumption event occurs). In some embodiments, certain steps of process 400 may occur at a given time interval.

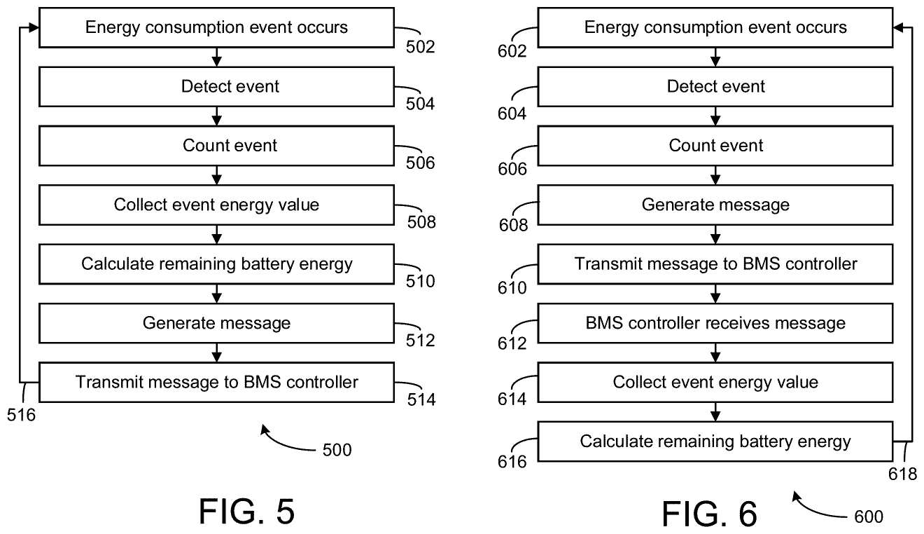

Referring now to FIG. 5, a process 500 illustrates the present technique for estimating battery life of FIG. 2, according to an exemplary embodiment. Process 500 may begin with similar steps 502, 504, 506, 508, and 510 as presented in FIG. 4. Following step 510, process 500 may proceed with step 512. Step 512 may involve generating a message containing the remaining battery life and a measured value. The process continues with step 514. Step 514 may involve transmitting the message to the BMS controller (e.g., BMS controller 166). The process continues with step 516. Step 516 may involve returning to step 502, which includes process 500 starting over.

Referring now to FIG. 6, a process 600 illustrates the present technique for estimating battery life of FIG. 3, according to an exemplary embodiment. Process 600 may begin with similar steps 602, 604, and 606 as presented FIG. 4. Following step 606, process 600 may proceed with step 608. Step 608 may involve generating a message containing a measured value, event identification, and event count. The process continues with step 610. Step 610 may involve transmitting the message generated in step 608 to the BMS controller (e.g., BMS controller 166). The process continues with step 612. Step 612 may involve the BMS controller receiving the message generated in step 608. The process continues with step 614. Step 614 may involve retrieving the event energy value from the energy database that is identified in the message generated in step 608. The process continues with step 616. Step 616 involves calculating the remaining battery life. In some embodiments, step 616 may involve subtracting the event energy value retrieved in step 614 from the battery energy capacity value. The process continues with step 618. Step 618 may involve returning to step 602, which includes process 600 starting over.

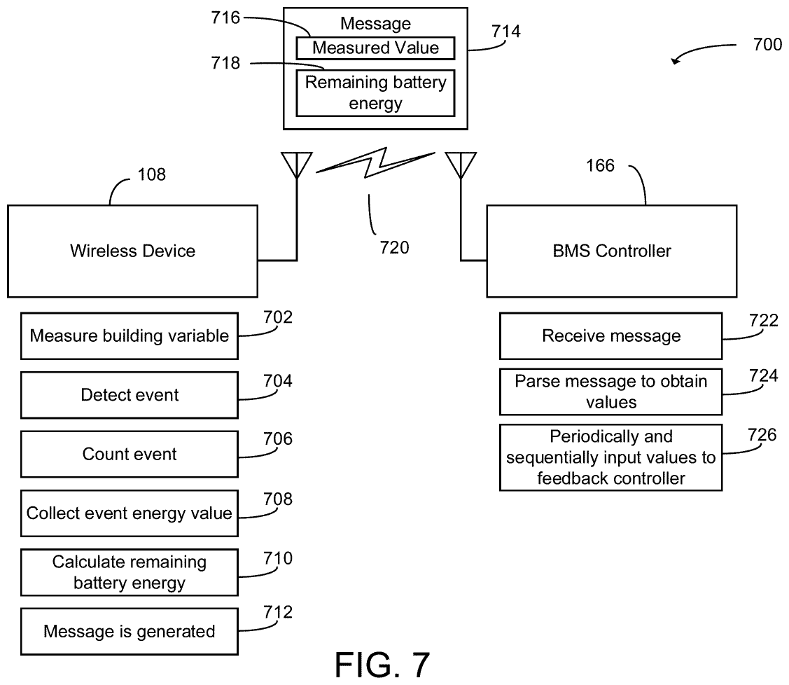

Referring now to FIG. 7 a layout 700 illustrates the present technique for estimating battery life of FIG. 5 with steps visualized to each device, according to an exemplary embodiment. Layout 700 includes wireless device 108. Wireless device 108 participates in step 702 which may involve measuring an environmental variable. In some embodiments, step 702 may include measuring more than one environmental variable. Wireless device 108 proceeds with step 704 which may involve detecting an event. In some embodiments, step 704 may include identifying the event. Wireless device 108 then proceeds with step 706 which may involve the event being counted. In some embodiments, step 706 may involve the events being summed.

Wireless device 108 then proceeds with step 708. Step 708 may involve the event energy value being collected from the energy database. In some embodiments, step 708 may involve the battery energy capacity value being collected. Wireless device 108 then proceeds with step 710. Step 710 may involve calculating the remaining battery life. In some embodiments, step 710 may involve subtracting the event energy value from the battery energy capacity value. Wireless device then concludes with step 712. Step 712 may include generating a message 714.

In some embodiments, message 714 may include measured value 716 and remaining battery energy 718. Message 714 is then transmitted wirelessly in step 720. In some embodiments, message 714 is transmitted in step 720 using a wired connection. BMS controller 166 receives message 714 in step 722. BMS controller 166 then proceeds with step 724. Step 724 may involve parsing the message to obtain measured value 716 and remaining battery energy 718. BMS controller 166 then proceeds with step 726. Step 726 may involve inputting measured value 716 to control the environmental variable.

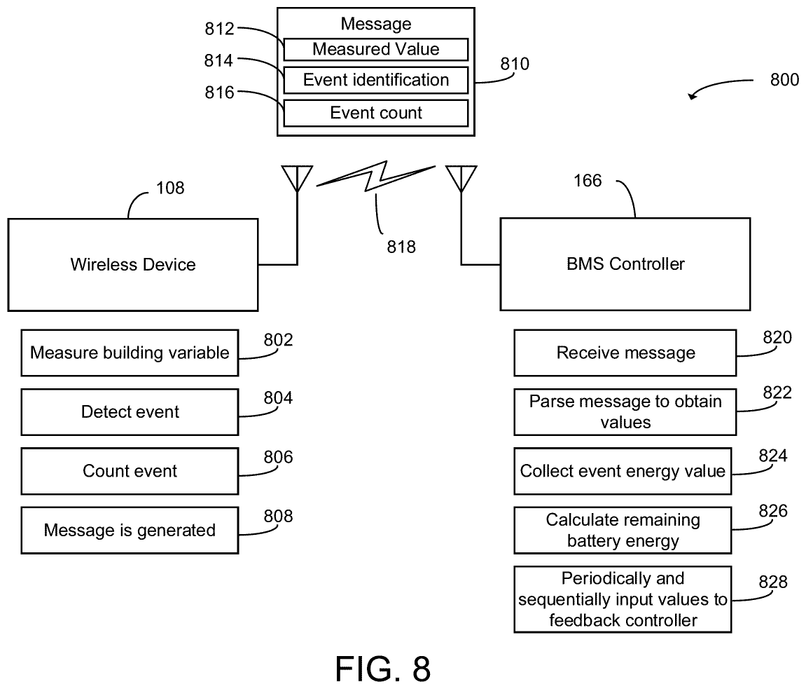

Referring now to FIG. 8 a layout 800 illustrates the present technique for estimating battery life of FIG. 6 with steps visualized to each device, according to an exemplary embodiment. Layout 800 includes wireless device 108. Wireless device 108 participates in similar steps 802, 804, and 806 as presented in FIG. 7. Wireless device 108 then proceeds with step 808. Step 808 may involve generating a message 810.

In some embodiments, message 810 may include a similar measured value 812, event identification 814, and event count 816. Message 810 is then transmitted wirelessly in step 818. In some embodiments, message 810 is transmitted in step 818 using a wired connection. BMS controller 166 receives message 810 in step 820. BMS controller 166 then proceeds with step 822. Step 822 may involve parsing the message to obtain measured value 812, event identification 814, and event count 816. BMS controller 166 may then proceed with step 824. Step 824 may involve the event energy value being collected from the energy database. In some embodiments, step 824 may involve the battery energy capacity value being retrieved. BMS controller 166 then proceeds with step 826. Step 826 may involve calculating the remaining battery life. In some embodiments, step 826 may involve subtracting the event energy value from the battery energy capacity value. BMS controller 166 then proceeds with step 828. Step 828 may involve inputting measured value 812 to control the environmental variable.

### Battery Energy Plots

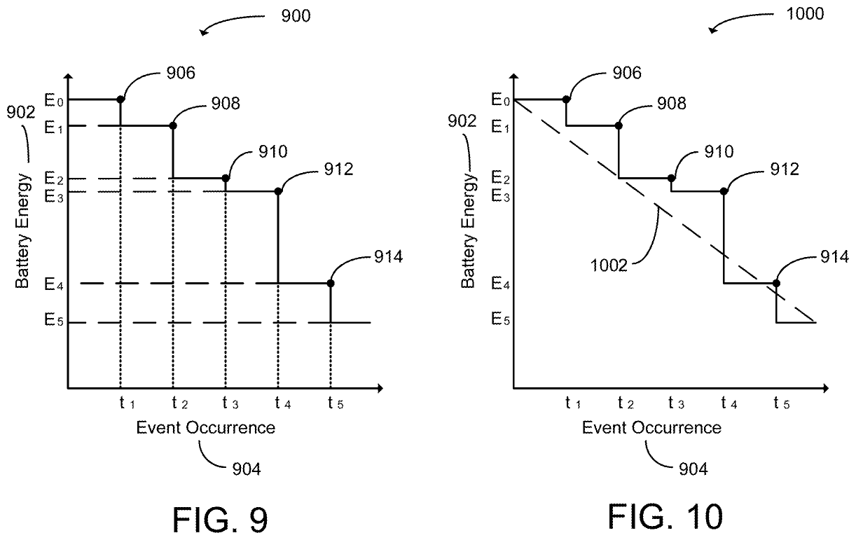

Referring now to FIG. 9, a plot 900 illustrates the energy consumption of the battery in the wireless device. Plot 900 includes a y-axis 902 which graphs the battery energy (e.g., Joules, etc.), an x-axis 904 which graphs the event occurrences, and energy-consumption events 906, 908, 910, 912, and 914. Energy-consumption events 906, 908, 910, 912, and 914 may involve wake, measuring, message generation, or any event that requires energy to execute by the wireless device. In some embodiments, the energy required by the energy-consumption events 906, 908, 910, 912, and 914 may differ depending on the event (e.g., wake, measuring, message generation, etc.) being executed.

In some embodiments, the energy remaining in the battery can be calculated by subtracting the energy consumed in the event from the battery energy capacity value, E₀. For example, when energy-consumption event 906 occurs at t₁, the energy consumed in the event is subtracted from the battery energy capacity value, E₀. The resulting value is the remaining battery energy value E₁. The remaining battery energy value E₁ is constant until energy-consumption event 908 occurs at t₂. In other embodiments, the energy remaining in the battery can be calculated by subtracting the energy consumed in the event from the previous remaining energy value. For example, when energy-consumption event 908 occurs at t₂, the energy consumed in the event is subtracted from the previous remaining energy value, E₁. The resulting value is a new remaining battery energy value E₂. The new remaining battery energy value E₂ is constant until energy-consumption event 910 occurs at t₃.

Referring now to FIG. 10, a plot 1000 illustrates the energy consumption of the battery in the wireless device used to predict the point at which the energy in the battery will be completely consumed. Plot 1000 includes similar axes 902 and 904 and similar energy-consumption events 906, 908, 910, 912, and 914. Plot 1000 also includes trendline 1002. Trendline 1002 may have an initial point at energy-consumption event 906. In some embodiments, trendline 1002 may be a best-fit curve (e.g., linear, logarithmic, etc.) of energy-consumption events 906, 908, 910, 912, and 914. In some embodiments, trendline 1002 may be used to estimate when the energy in the battery will be completely consumed. In some embodiments, trendline 1002 may be used to signal the battery is at a threshold energy value. For example, when trendline 1002 reaches a value of 10% of the total energy of a battery, a signal may be transmitted to a controller indicating a need to replace the battery.

### Configuration of Exemplary Embodiments

The construction and arrangement of the systems and methods as shown in the various exemplary embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements can be reversed or otherwise varied and the nature or number of discrete elements or positions can be altered or varied. Accordingly, all such modifications are intended to be included within the scope of the present disclosure. The order or sequence of any process or method steps can be varied or re-sequenced according to alternative embodiments. Other substitutions, modifications, changes, and omissions can be made in the design, operating conditions and arrangement of the exemplary embodiments without departing from the scope of the present disclosure.

The present disclosure contemplates methods, systems and program products on any machine-readable media for accomplishing various operations. The embodiments of the present disclosure can be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

Although the figures show a specific order of method steps, the order of the steps may differ from what is depicted. Also two or more steps can be performed concurrently or with partial concurrence. Such variation will depend on the software and hardware systems chosen and on designer choice. All such variations are within the scope of the disclosure. Likewise, software implementations could be accomplished with standard programming techniques with rule based logic and other logic to accomplish the various connection steps, processing steps, comparison steps and decision steps.

What is claimed is:

1. A wireless device comprising:
a battery configured to store and discharge energy to power the wireless device;
an event detector configured to detect one or more energy consumption events occurring in the wireless device, each of the energy consumption events corresponding to a function performed by the wireless device and having a pre-determined amount of energy consumption associated therewith;
an event counter configured to accumulate a total number of each of the energy consumption events detected by the event detector; and
an energy database storing energy data indicating the pre-determined amount of energy consumption associated with each of the energy consumption events; and
an energy calculator configured to determine an amount of energy remaining in the battery using the total number of each of the energy consumption events and the pre-determined amount of energy consumption associated with each of the energy consumption events; and
a wireless radio configured to transmit a message containing the amount of energy remaining in the battery.

2. The wireless device of claim 1, wherein the wireless device comprises a sensor and the message comprises one or more measurements of an environmental variable recorded by the sensor.

3. The wireless device of claim 1, wherein the event detector is configured to identify an energy consumption event and classify the energy consumption event as one or a plurality of different energy consumption events.

4. The wireless device of claim 1, wherein the event counter is configured to increment a counter associated with the energy consumption events each time that an energy consumption event is detected.

5. The wireless device of claim 1, wherein the event counter is configured to sum a counter associated with the energy consumption events each time that an energy consumption event is detected.

6. The wireless device of claim 1, wherein the energy data stored in the energy database further comprises an indication of energy capacity of the battery.

7. The wireless device of claim 1, wherein the energy calculator configured to determine the amount of energy remaining in the battery subtracting the pre-determined amount of energy consumption from a battery energy capacity value.

8. A method for operating a wireless device in a building control system, the method comprising:
storing energy in a battery of the wireless device and discharging energy from the battery to power the wireless device;
detecting one or more energy consumption events occurring in the wireless device, each of the energy consumption events corresponding to a function performed by the wireless device and having a pre-determined amount of energy consumption associated therewith;
accumulating a total number of each of the energy consumption events;
obtaining, from an energy database, the pre-determined amount of energy consumption associated with each of the energy consumption events; and
determining an amount of energy remaining in the battery using the total number of each of the energy consumption events and the pre-determined amount of energy consumption associated with each of the energy consumption events.

9. The method of claim 8, wherein the one or more energy consumption events comprises a measurement of an environmental variable recorded by a sensor.

10. The method of claim 8, wherein detecting the one or more energy consumption events of the wireless device further comprises identifying the one or more energy consumption events of the wireless device.

11. The method of claim 8, wherein counting the one or more energy consumption events of the wireless device further comprises summing the one or more energy consumption events of the wireless device.

12. The method of claim 8, wherein obtaining the pre-determined amount of energy consumption associated with each of the energy consumption events further comprises obtaining a battery energy capacity value.

13. The method of claim 8, wherein determining the amount of energy remaining in the battery comprises:
obtaining the pre-determined amount of energy consumption; and
subtracting the pre-determined amount of energy consumption from a battery energy capacity value.

14. The method of claim 8, wherein determining the amount of energy remaining in the battery comprises:
obtaining the pre-determined amount of energy consumption; and
subtracting the pre-determined amount of energy consumption from a previous amount of energy remaining in the battery

15. A building control system comprising:
a wireless device comprising:
a battery configured to store and discharge energy to power the wireless device;
an event detector configured to detect one or more energy consumption events occurring in the wireless device, each of the energy consumption events corresponding to a function performed by the wireless device and having a pre-determined amount of energy consumption associated therewith;
an event counter configured to accumulate a total number of each of the energy consumption events detected by the event detector; and
a wireless radio configured to transmit a message comprising the total number of each of the energy consumption events; and
a controller comprising:
a message parser configured to parse the message to extract the total number of each of the energy consumption events;
an energy database storing energy data indicating the pre-determined amount of energy consumption associated with each of the energy consumption events; and
an energy calculator configured to calculate an amount of energy remaining in the battery using the total number of each of the energy consumption events and the pre-determined amount of energy consumption associated with each of the energy consumption events.

16. The building control system of claim 15, wherein the wireless device comprises a sensor and the message comprises one or more measurements of an environmental variable recorded by the sensor.

17. The building control system of claim 15, wherein the event detector is configured to identify an energy consumption event and classify the energy consumption event as one or a plurality of different energy consumption events, each of the different energy consumption events corresponding to a different function performed by the wireless device.

18. The building control system of claim 15, wherein the event counter is configured to increment a counter associated with the energy consumption events each time that an energy consumption event is detected.

19. The building control system of claim 15, wherein the event counter is configured to sum a counter associated with the energy consumption events each time that an energy consumption event is detected.

20. The building control system of claim 15, wherein the energy data stored in the energy database further comprises an indication of a battery energy capacity value.
